(19) United States
(12) Patent Application Publication
(10) Pub. No.: US 2026/0190446 A1
(43) Pub. Date: Jul. 2, 2026

(54) SELECTIVE NANOWIRE RELEASE AND BACKFILL FOR TRANSISTOR CHANNEL STRESS ENGINEERING IN NANOWIRE FIELD EFFECT TRANSISTORS

(71) Applicant: Intel Corporation, Santa Clara, CA (US)

(72) Inventors: Chia-Ching Lin, Portland, OR (US); Kan Zhang, Hillsboro, OR (US); Tahir Ghani, Portland, OR (US); Yang Zhang, Rio Rancho, NM (US); Chung-Hsun Lin, Portland, OR (US); Chun Wing Yeung, Portland, OR (US); Ting-Hsiang Hung, Beaverton, OR (US); Feng Zhang, Portland, OR (US); Guowei Xu, Portland, OR (US); Tao Chu, Portland, OR (US)

(73) Assignee: Intel Corporation, Santa Clara, CA (US)

(21) Appl. No.: 19/002,234

(22) Filed: Dec. 26, 2024

(51) Int. Cl. H10D 84/01; H10D 84/85

(52) U.S. Cl. CPC H10D 84/017; H10D 84/0167; H10D 84/851

(57) ABSTRACT

Devices, integrated circuit transistor structures, systems, and techniques are described herein related to gate all around field effect transistor circuits having an n-type transistor integrated with a p-type transistor such that each has stress engineering in the channel material thereof. The nanowires of the p-type transistor are released and surrounded by a sacrificial flowable oxide structure during source and drain material growth to apply compressive stress to the channel material. The n-type transistor source and drain are grown in the presence of a sacrificial lattice matched material to apply tensile stress to the channel material, and the nanowires are subsequently released. After removal of the sacrificial flowable oxide structure, gate structures are coupled to the n-type and p-type transistors.

### BACKGROUND

Higher performance, lower cost, increased miniaturization, and greater density of integrated circuits (ICs) are ongoing goals of the electronics industry. To maintain the pace of increasing transistor performance, for example, multi-gate transistors such as gate-all-around (GAA) or nanowire transistors are being deployed. In such devices, the gate structure surrounds the channel region on all sides of each nanowire (or nanoribbon) of semiconductor material for improved drive current, device control, and other advantages. The nanowires or nanoribbons of semiconductor material are contacted on opposite sides by source and drain structures, which may be epitaxially grown materials.

Currently, there are difficulties in improving device performance related to stress engineering between n-type and p-type transistors due to limitations in the fabrication of the source and drain structures. It is with respect to these and other considerations that the present improvements have been needed. Such improvements may become critical as the desire to deploy integrated circuits with multi-gate transistor structures such as nanowire or nanoribbon field effect transistors becomes more widespread.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 is a flow diagram illustrating exemplary methods 100 for forming integrated circuit structures with an n-type transistor integrated with a p-type transistor such that the n-type transistor and the p-type transistor have selective stress engineering;

FIGS. 2, 3, 4, 5, 6, 7, 8, 9, 10, 11, 12, 13, 14, 15, 16, 17, 18, 19, and 20 are cross-sectional side views taken at a gate cut of example n-type transistor structures and example p-type transistor structures as particular fabrication operations of the methods of FIG. 1 are performed;

FIG. 21 is a cross-sectional side view of the integrated circuit structure of FIG. 20 incorporated in a multi-layer integrated circuit device structure;

FIG. 22 illustrates exemplary systems employing integrated circuit structures with an n-type transistor integrated with a p-type transistor such that the n-type transistor and the p-type transistor have selective stress engineering; and

FIG. 23 is a block diagram of a computing device, all arranged in accordance with at least some embodiments of the present disclosure.

### DETAILED DESCRIPTION

One or more embodiments or implementations are now described with reference to the enclosed figures. While specific configurations and arrangements are discussed, it should be understood that this is done for illustrative purposes only. Persons skilled in the relevant art will recognize that other configurations and arrangements may be employed without departing from the spirit and scope of the description. It will be apparent to those skilled in the relevant art that techniques and/or arrangements described herein may also be employed in a variety of other systems and applications other than what is described herein.

Reference is made in the following detailed description to the accompanying drawings, which form a part hereof, wherein like numerals may designate like parts throughout to indicate corresponding or analogous elements. It will be appreciated that for simplicity and/or clarity of illustration, elements illustrated in the figures have not necessarily been drawn to scale. For example, the dimensions of some of the elements may be exaggerated relative to other elements for clarity. Further, it is to be understood that other embodiments may be utilized, and structural and/or logical changes may be made without departing from the scope of claimed subject matter. It should also be noted that directions and references, for example, up, down, top, bottom, over, under, and so on, may be used to facilitate the discussion of the drawings and embodiments and are not intended to restrict the application of claimed subject matter. Therefore, the following detailed description is not to be taken in a limiting sense and the scope of claimed subject matter defined by the appended claims and their equivalents.

In the following description, numerous details are set forth. However, it will be apparent to one skilled in the art, that the present invention may be practiced without these specific details. In some instances, well-known methods and devices are shown in block diagram form, rather than in detail, to avoid obscuring the present invention. Reference throughout this specification to “an embodiment” or “one embodiment” means that a particular feature, structure, function, or characteristic described in connection with the embodiment is included in at least one embodiment of the invention. Thus, the appearances of the phrase “in an embodiment” or “in one embodiment” in various places throughout this specification are not necessarily referring to the same embodiment of the invention. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description of the invention and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items. Herein, the term “predominantly” indicates not less than 50% of a particular material or component while the term “substantially pure” indicates not less than 99% of the particular material or component and the term “pure” indicates not less than 99.9% of the particular material or component. Unless otherwise indicated, such material percentages are based on atomic percentage. Herein the term concentration is used interchangeably with material percentage and also indicates atomic percentage unless otherwise indicated.

The terms “coupled” and “connected,” along with their derivatives, may be used herein to describe structural relationships between components. It should be understood that these terms are not intended as synonyms for each other. Rather, in particular embodiments, “connected” may be used to indicate that two or more elements are in direct physical or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship, an electrical relationship, a functional relationship, etc.).

The terms “over,” “under,” “between,” “on”, and/or the like, as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features. The term immediately adjacent indicates such features are in direct contact. Furthermore, the terms “substantially,” “close,” “approximately,” “near,” and “about,” generally refer to being within +/−10% of a target value. The term layer as used herein may include a single material or multiple materials. As used in throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C. The terms “lateral”, “laterally adjacent” and similar terms indicate two or more components are aligned along a plane orthogonal to a vertical direction of an overall structure. As used herein, the terms “monolithic”, “monolithically integrated”, and similar terms indicate the components of the monolithic overall structure form an indivisible whole not reasonably capable of being separated.

Devices, transistor structures, integrated circuit dies, apparatuses, systems, and techniques are described herein related to integrated circuits with PMOS gate-all-around field effect transistors (GAA-FETs) having source and drain structures grown in the presence of a flowable oxide material on and between the nanowires thereof and NMOS GAA-FETs having source and drain structures grown in the presence of a sacrificial lattice matched material on and between the nanowires thereof for improved stress engineering between n-type and p-type transistors.

As discussed, multi-gate transistors such as gate-all-around (GAA) or nanowire transistors are being deployed in advanced integrated circuit devices. As used herein, the terms nanowire, nanoribbon, stacked semiconductor structure, and similar terms are used substantially interchangeably to indicate a semiconductor material that extends from a source to a drain such that the semiconductor material is one of two or more such material structures that are separated and vertically aligned. The multiple semiconductor material structures each couple to the same source and drain, and are vertically separated by a gate structure, which may include a gate dielectric and a gate electrode. Thereby, the field effect transistor or device includes a source, a drain, and a stack of semiconductor structures extending between the source and the drain. The source and drain are epitaxial to the semiconductor structures. As used herein the term epitaxial to or similar terms indicate the materials are substantially lattice matched. The stack of semiconductor structures (e.g., two to about eight semiconductor structures) are controlled by the same gate electrode, and work in concert as the channel of the device. As used herein, the term channel region of a semiconductor structure indicates a region of a material layer adjacent to a gate dielectric and gate electrode that is to be controlled by the gate electrode to switch the transistor structure in operation. Notably, a region of a material layer need not be in operation to be characterized as a channel region, channel material, or the like. The term semiconductor structure is used broadly to include nanowires, nanoribbons, and similar terms.

A complementary metal-oxide-semiconductor (CMOS) device or apparatus includes n-type metal-oxide-semiconductor (NMOS) transistors integrated with p-type metal-oxide-semiconductor (PMOS) transistors. The terms n-type and p-type as well as NMOS and PMOS are used in their ordinary meaning to indicate the conductor and dopant type of the semiconductor device. N-type transistors use electrons as carriers and have n-type doped source and drain regions while p-type transistors use holes as carriers and have p-type doped source and drain regions. Exemplary n-type dopants for the source and drain regions include phosphorous and arsenic, such that, for example, the source and drain regions of n-type transistors may be phosphorous and/or arsenic doped epitaxial silicon. Exemplary p-type dopants for the source and drain regions include boron and gallium, such that, for example, the source and drain regions of p-type transistors may be boron and/or gallium doped epitaxial silicon germanium. However, other material systems may be used.

As discussed, current GAA-FET integrated circuits have difficulties including improving device performance related to stress engineering between n-type and p-type transistors due to limitations in the fabrication of the source and drain structures and other reasons. As used herein, the term stress is indicative of a force applied to a material due to surrounding materials and encompasses the related strain, which is any deformation of the material due to the applied stress. In some embodiments, nanowires of PMOS transistors are released prior to fabrication of the source and drain structures of the PMOS transistors. As used herein, the term nanowire release and similar terms indicate the process of removing sacrificial substantially lattice matched materials from between the nanowires. For example, the nanowires may be substantially monocrystalline silicon, and the removed sacrificial materials may be silicon germanium. After nanowire release, a sacrificial material structure including a flowable oxide is formed between the nanowires and the source and drain structures are grown from exposed ends of the nanowires in the presence of the sacrificial material structure. Thereby, the desired stress for PMOS devices (i.e., negative stress or compressive stress) is set during the epitaxial growth of the p-type source and drain structures. The sacrificial material structure is then removed.

For PMOS transistors, the source and drain structures are formed in the presence of the substantially lattice matched sacrificial materials, and the desired stress for NMOS devices (i.e., positive stress) is locked in or set during the epitaxial growth of the n-type source and drain structures. The nanowires of the NMOS sacrificial materials are then released with some of the sacrificial material structure advantageously remaining as part of the spacer of the NMOS transistor. Processing then continues with simultaneous formation of the gate structures of the PMOS and NMOS, frontside contacts and metallization, and so on. The resultant integrated circuit includes an n-type transistor having nanowires extending between an n-type source and n-type drain, a gate coupled to the nanowires, and spacers between the gate and the source and drain, such that the spacer includes a dielectric material and germanium, such as a dielectric material portion and a silicon germanium portion, and a p-type transistor having nanowires extending between a p-type source and p-type drain, a gate coupled to the nanowires, and spacers between the gate and the source and drain, such that the spacer includes a dielectric material and is absent germanium. The resultant NMOS and PMOS transistors have advantageous selective stress engineering with the NMOS transistors having positive stress and the PMOS transistors having negative stress (i.e., compressive stress) being advantageous.

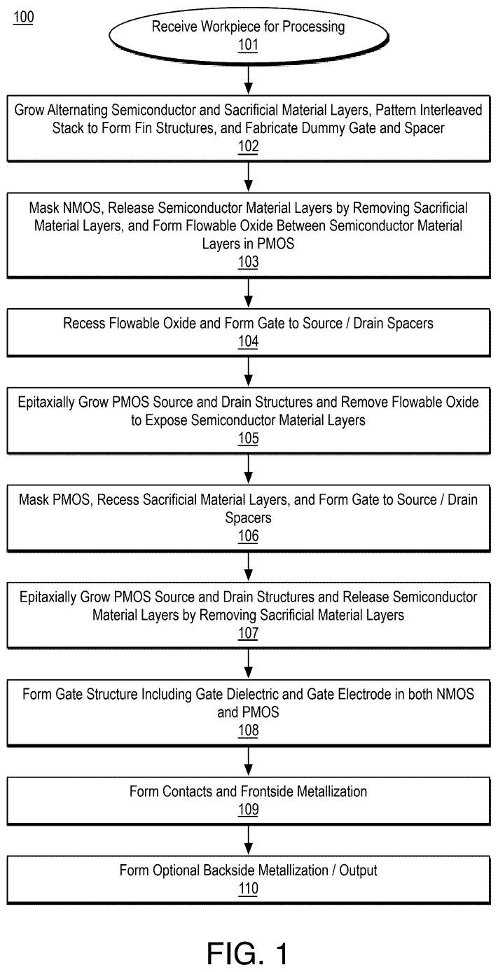

FIG. 1 is a flow diagram illustrating exemplary methods 100 for forming integrated circuit structures with an n-type transistor integrated with a p-type transistor such that the n-type transistor and the p-type transistor have selective stress engineering, arranged in accordance with at least some embodiments of the present disclosure. For example, methods 100 may be implemented to fabricate integrated circuit structure 2000 or any other integrated circuit structures discussed herein. In the illustrated implementation, methods 100 may include one or more operations as illustrated by operations 101-110. However, embodiments herein may include additional operations, certain operations being omitted, or operations being performed out of the order provided.

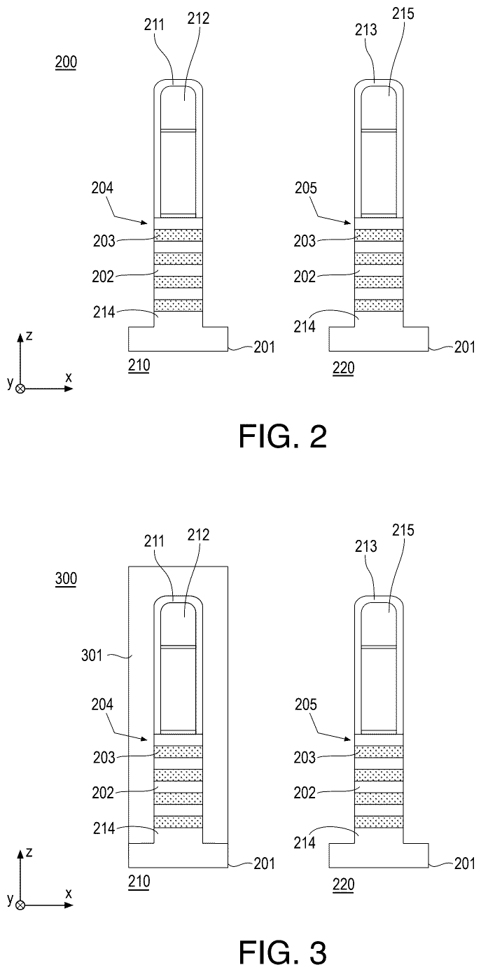

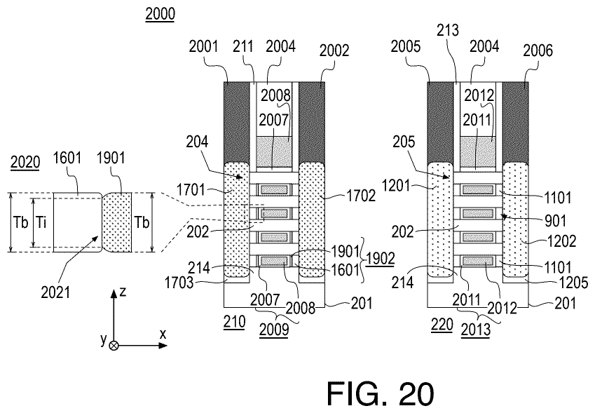

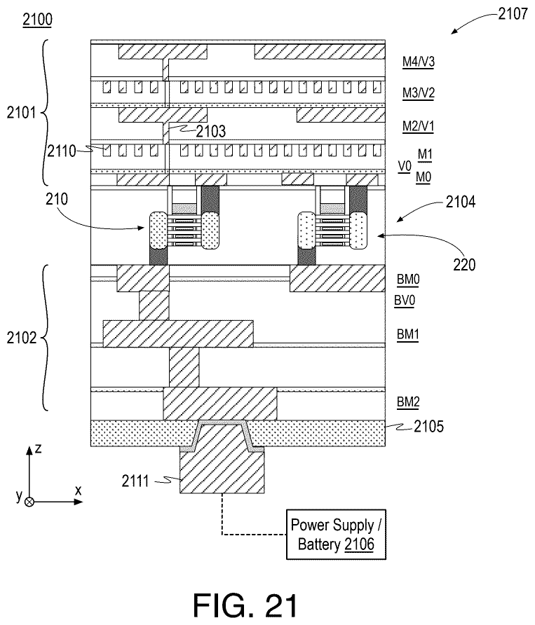

FIGS. 2, 3, 4, 5, 6, 7, 8, 9, 10, 11, 12, 13, 14, 15, 16, 17, 18, 19, and 20 are cross-sectional side views taken at a gate cut of example n-type transistor structures and example p-type transistor structures as particular fabrication operations of methods 100 are performed, arranged in accordance with at least some implementations of the present disclosure. FIG. 21 is a cross-sectional side view of the integrated circuit structure of FIG. 20 incorporated in a multi-layer integrated circuit device structure, arranged in accordance with at least some implementations of the present disclosure.

Processing begins at operation 101, where a workpiece such as a substrate is received for processing. The substrate may include any suitable substrate as discussed herein such as a silicon wafer or the like. In some embodiments, the substrate includes underlying devices or electrical interconnects. Processing continues at operation 102, where alternating layers of semiconductor material layers and sacrificial layers are formed over the workpiece or substrate, the alternating (or interleaved) layers of semiconductor material layers and sacrificial layers are patterned to form fin structures of the interleaved stack of semiconductor material layers and sacrificial layers, and dummy gate and spacer structures are formed.

The alternating layers of semiconductor material layers and sacrificial layers may be formed using any suitable technique or techniques such as epitaxial growth techniques, deposition techniques or the like. The semiconductor material layers, and sacrificial layers may include any suitable materials and may have any thickness characteristics discussed herein below. The alternating layers of semiconductor material layers and sacrificial layers may be patterned into any number of fins using any suitable technique or techniques such as lithography and etch techniques. In some embodiments, the patterning includes one or more etches such to define the fin critical dimensions of the semiconductor material layers, and the formation of dummy gate and spacer structures. After patterning, the resultant semiconductor structures or nanoribbons are defined for use in a transistor structure. In some embodiments, the semiconductor material layers are silicon such as substantially monocrystalline silicon and the sacrificial layers are silicon germanium such as substantially monocrystalline silicon germanium.

FIG. 2 is a cross-sectional side view of an example integrated circuit structure 200 taken at a gate cut of an n-type transistor structure 210 and a p-type transistor structure 220. As shown, n-type transistor structure 210 and p-type transistor structure 220 are built-up over a shared substrate 201 and include semiconductor structures 202 interleaved with sacrificial material structures 203. Substrate 201 may include any suitable material or materials and, in some embodiments, substrate 201 includes a material or materials having the same or a similar composition with respect to semiconductor structures 202. In some embodiments, substrate 201 and semiconductor structures 202 include a Group IV material (e.g., silicon). In some embodiments, substrate 201 and semiconductor structures 202 include a substantially monocrystalline material. In some embodiments, substrate 201 includes a buried insulator layer (e.g., SiO₂), for example, of a semiconductor-on-insulator (SOI) substrate and/or isolation insulator regions and the like.

Semiconductor structures 202 may include any number of layers and may be characterized as semiconductor structures, channel semiconductors, nanoribbons, nanowires, or the like. As shown, n-type transistor structure 210 include a stack 204 of semiconductor structures 202 and p-type transistor structure 220 include a stack 205 of semiconductor structures 202. In some embodiments, semiconductor structures 202 are the same between n-type transistor structure 210 and p-type transistor structure 220. However, they may be different in some embodiments. Stacks 204, 205 may include any number of semiconductor structures 202 such as two, three, four (as illustrated), five, six, seven, eight or more layers with even numbers of semiconductor structures 202 typically being deployed. Semiconductor structures 202 are separated by and interleaved with sacrificial material structures 203, which will be removed as discussed below to release semiconductor structures 202. In some embodiments, semiconductor structures 202 are silicon such as monocrystalline silicon and sacrificial material structures 203 are silicon germanium. Semiconductor structures 202 and sacrificial material structures 203 may have any suitable thicknesses (i.e., measured in the z-dimension) such as thicknesses in the range of about 5 to 12 nm. During formation of fins of n-type transistor structure 210 and p-type transistor structure 220, dummy gate structure 212 and dielectric spacer 211 are formed. The fabrication of the fins of n-type transistor structure 210 and p-type transistor structure 220 may establish any suitable source to drain length defined in the x-dimension such as a length in the range of 3 nm to 20 nm. Also as shown, the patterning may form subfins 214. Dummy gate structures 215 and spacer 213 may be any suitable materials such as polysilicon and dielectric materials, respectively.

Returning to FIG. 1, processing continues at operation 103, where the n-type transistor structures are masked, the semiconductor material layers (e.g., nanoribbons) are released for the p-type transistors by removing the sacrificial material structures of the PMOS transistors, and a sacrificial structure including a flowable oxide is formed on and between the released semiconductor material layers. The NMOS transistor mask may be any suitable material or materials that protect n-type transistor structures during selective processing of the PMOS transistors, such as silicon oxide. In some embodiments, mask layer is formed by applying a bulk material layer, optional planarization of the bulk material layer, forming a patterned layer such as a patterned resist layer on the bulk material layer, and etch processing to form a patterned mask layer.

The sacrificial material to be present during source and drain formation of the PMOS transistors, such as a sacrificial material structure including a flowable oxide, may be formed using any suitable technique or techniques. In some embodiments, a conformal layer such as a dielectric liner material is formed using, for example, atomic layer deposition (ALD), plasma enhanced chemical vapor deposition (PECVD), chemical vapor deposition (CVD), or the like. The optional liner is then followed by a bulk material such as a flowable oxide. As used herein, the term flowable oxide is used to indicate an inorganic polymer material such as a polymerized form of silicon oxide or other inorganic dielectric dissolved in a solvent. Such materials can be applied using coating processes such as spin on coating, which allows it to flow and conform to a surface as well as provide a fill of the material. In some embodiments, the coating process is followed by a cure process and/or a planarization process.

FIG. 3 is a cross-sectional side view of an example integrated circuit structure 300 similar to integrated circuit structure 200, after formation of a mask layer 301 to cover n-type transistor structure 210 while exposing p-type transistor structure 220. Mask layer 301 may be any suitable material or materials such as silicon oxide or other protective materials. In some embodiments, mask layer 301 is formed by applying a bulk material layer, planarization, and patterning. Mask layer 301 covers n-type transistor structure 210 while exposing p-type transistor structure 220 for subsequent processing to apply compressive stress engineering to semiconductor structures 202 of p-type transistor structure 220. It is noted that any material build-up or damage to mask layer 301 during processing of p-type transistor structure 220 is not illustrated for the sake of clarity of presentation, as it is ultimately removed.

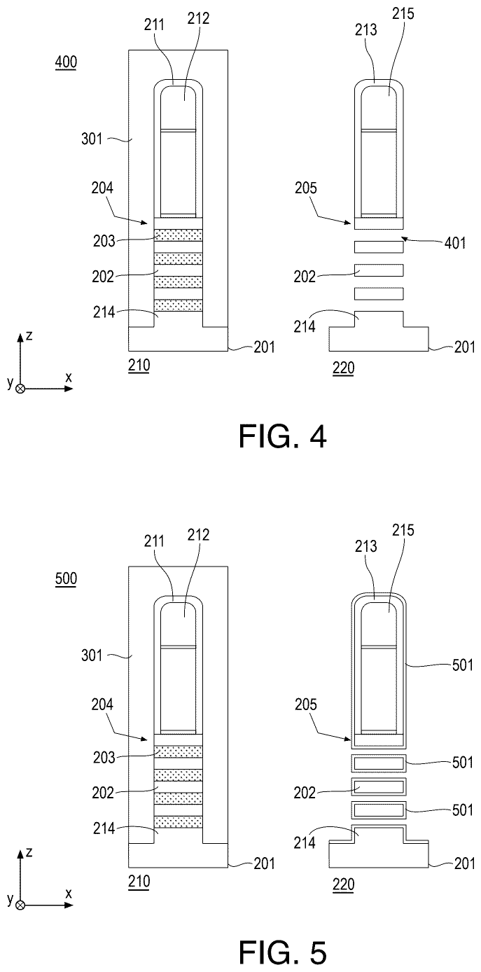

FIG. 4 is a cross-sectional side view of an example integrated circuit structure 400 similar to integrated circuit structure 300, after removal of sacrificial material structures 203 of p-type transistor structure 220 to release semiconductor structures 202 and to form openings 401. It is noted that semiconductor structures 202 are supported by structures into and out of the page with respect to the view of FIG. 4. Sacrificial material structures 203 may be removed using any suitable technique or techniques such as selective wet etch techniques. For example, silicon germanium sacrificial material structures 203 may be selectively etched with respect to the silicon of semiconductor structures 202 to release semiconductor structures 202 (e.g., nanowire release).

FIG. 5 is a cross-sectional side view of an example integrated circuit structure 500 similar to integrated circuit structure 400, after formation of a conformal dielectric liner 501 on exposed surfaces of each of semiconductor structures 202, exposed substrate 201, and dielectric spacers 213. Conformal dielectric liner 501 may be formed using any suitable technique or techniques such as ALD, PECVD, or CVD. Conformal dielectric liner 501 may be any suitable dielectric material such as silicon oxide, silicon nitride, or silicon oxynitride to any suitable thickness such as a thickness in the range of 1 nm to 4 nm.

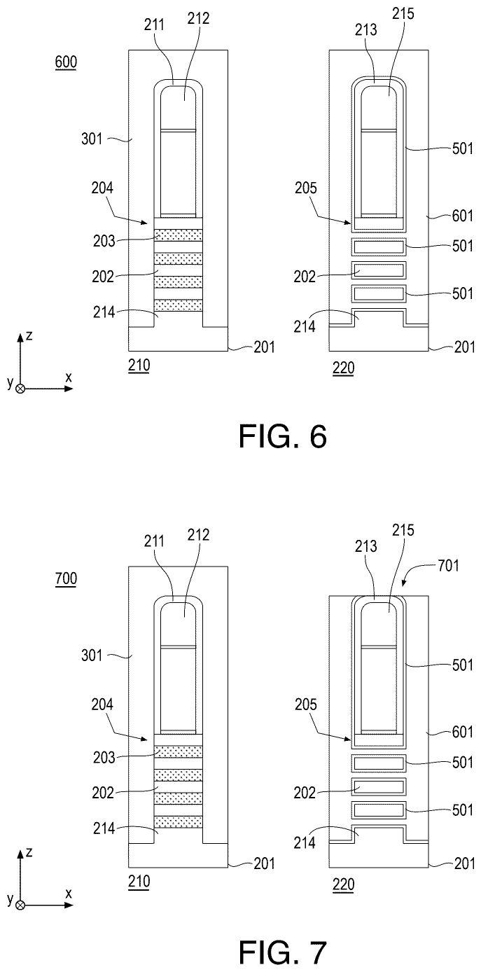

FIG. 6 is a cross-sectional side view of an example integrated circuit structure 600 similar to integrated circuit structure 500, after deposition of a flowable dielectric material 601 on conformal dielectric liner 501 and over each of semiconductor structures 202, exposed substrate 201, and dielectric spacers 213. Flowable dielectric material 601 may be deposited using any suitable technique or techniques such as spin on coating techniques. For example, a liquid precursor including flowable dielectric material 601 (i.e., including a silicon-based polymer) may be deposited over substrate 201 and substrate 201 may be spun to distribute the liquid. A subsequent anneal may be performed, leaving flowable dielectric material 601 surrounding and between each of semiconductor structures 202. Flowable dielectric material 601 may be any suitable flowable material including an inorganic polymer material. In some embodiments, flowable dielectric material 601 is a polymerized form of silicon oxide or other inorganic dielectric such as silicon nitride, silicon oxynitride, silicon carbide, or silicon oxygen carbon dissolved in a solvent. In some embodiments, flowable dielectric material 601 is applied using a coating process such as spin on coating. In some embodiments, the coating process is followed by a cure process and/or a planarization process to form flowable dielectric material 601.

Returning to FIG. 1, processing continues at operation 104, where the flowable oxide structure may be recessed and gate to source and gate to drain spacers may be formed. For example, the dielectric spacers ultimately insulate a gate structure from each of a source structure and a drain structure, with the source structure, the drain structure, and the gate structure being formed later in the process flow. The flowable oxide structure may be recessed and the dielectric spacer may be formed using any suitable technique or techniques. In some embodiments, the flowable oxide structure is recessed using a selective etch that selectively removes the materials of the flowable oxide structure (e.g., the flowable oxide fill and dielectric liner). In some embodiments, the dielectric spacers are then formed in the recess using deposition and anisotropic directional etching techniques.

FIG. 7 is a cross-sectional side view of an example integrated circuit structure 700 similar to integrated circuit structure 600, after chemical mechanical polish of flowable dielectric material 601 to provide a surface 701 where dielectric spacer 213, flowable dielectric material 601, and conformal dielectric liner 501 are exposed. For example, an etch selectivity may be present between the material(s) of dielectric spacer 213 and conformal dielectric liner 501 and the material of flowable dielectric material 601.

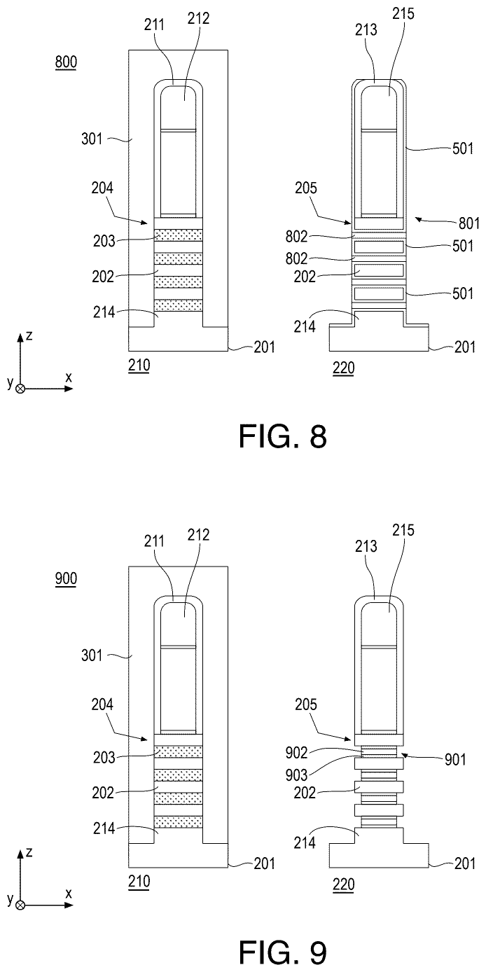

FIG. 8 is a cross-sectional side view of an example integrated circuit structure 800 similar to integrated circuit structure 700, after removal of portions of flowable dielectric material 601 to provide a sidewall 801 that includes exposed portions of conformal dielectric liner 501 and exposed portions of flowable dielectric material structures 802. As shown, flowable dielectric material structures 802 extend parallel to semiconductor structures 202 and are between adjacent ones of semiconductor structures 202.

FIG. 9 is a cross-sectional side view of an example integrated circuit structure 900 similar to integrated circuit structure 800, after recessing flowable dielectric material structures 802 and conformal dielectric liner 501 to form recessed dielectric structures 901 between each of semiconductor structures 202. As shown, in some embodiments, recessed dielectric structures 901 each include a flowable dielectric material structure 902 sandwiched between conformal dielectric liner structures 903.

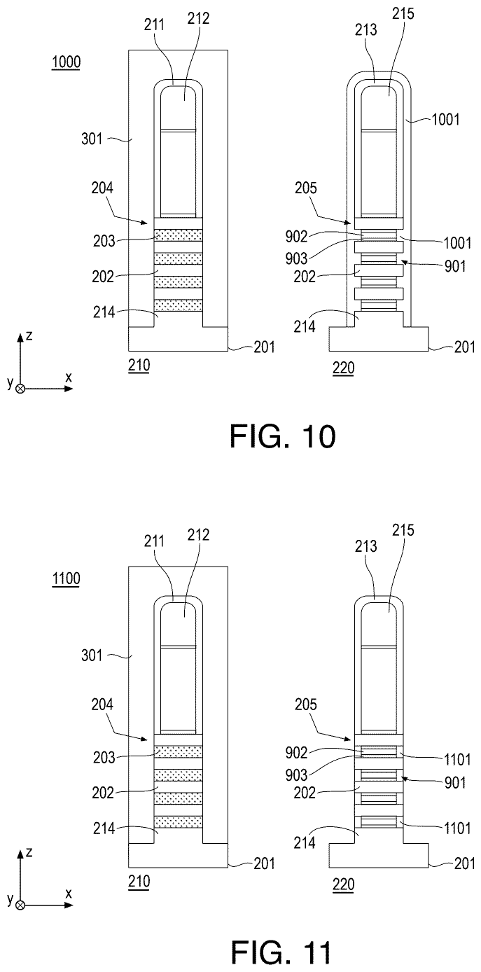

FIG. 10 is a cross-sectional side view of an example integrated circuit structure 1000 similar to integrated circuit structure 900, after deposition of a spacer material 1001. Spacer material 1001 may be any suitable material such as silicon oxide, silicon nitride, silicon oxynitride, or the like. Spacer material 1001 may be formed using any suitable technique or techniques such as ALD, PECVD, or CVD.

FIG. 11 is a cross-sectional side view of an example integrated circuit structure 1100 similar to integrated circuit structure 1000, after removal of portions of spacer material 1001 to provide spacer structures 1101. For example, the portions of spacer material 1001 may be removed using anisotropic directional etching techniques. As discussed, spacer structures 1101 may be any suitable dielectric material such as silicon oxide (i.e., a dielectric including silicon and oxygen), silicon nitride (i.e., a dielectric including silicon and nitrogen), silicon oxynitride (i.e., a dielectric including silicon, oxygen, and nitrogen). However, other material systems may be used. Notably, due to the early release of semiconductor structures 202 in the absence of spacer structures 1101, no material of sacrificial material structures 203, such as silicon germanium, is present and spacer structures 1101 are absent germanium. As used herein, the term absent with respect to a material or compound indicates the material or compound has no or only trace amounts of the material (i.e., <0.001% of a material). For example, spacer structures 1101 are substantially pure or pure compounds of the applied dielectric material. Spacer structures 1101 will electrically isolate a gate structure from a source structure and from a drain structure for improved device performance.

Returning to FIG. 1, processing continues at operation 105, where epitaxial p-type source and drain materials are grown or deposited via the exposed ends of the stacks of interleaved semiconductor material layers in the presence of the discussed flowable dielectric material structures for the PMOS transistors, and the flowable dielectric material structures are then removed. As discussed, the presence of the flowable dielectric material structures sets or locks in the desired stress engineering (i.e., compressive stress) in the channel of the PMOS transistor structures. Notably, the selective nanowire release, application of flowable dielectric structures, and epitaxial growth in the presence of the flowable oxide structures for the PMOS transistor structures is not applied to NMOS transistor structures, which will be separately processed to provide tensile stress in the channel of the NMOS transistor structures. It is noted that methods 100 provide a particular NMOS and PMOS masking technique. However, any order of operations, masking sequence, or the like may be deployed as is known in the art such that the selective epitaxial growth in the presence of flowable dielectric material structures for PMOS transistors and epitaxial growth in the presence of substantially lattice matched sacrificial materials for PMOS transistors is maintained.

The epitaxial growth of source and drain structures in the presence of flowable dielectric material structures may be performed using any suitable technique or techniques. In some embodiments, a single bulk material is grown or deposited. In some embodiments, an epitaxial nucleation layer may be grown or deposited, followed by bulk growth or deposition. In some embodiments, the epitaxial nucleation layer and bulk epitaxial materials are grown or deposited in the same process chamber using differing deposition parameters. The p-type source and drain materials may be any suitable materials having p-type conductivity such as doped silicon germanium or doped silicon. Exemplary p-type dopants for the source and drain regions include boron and gallium, such that, for example, the source and drain regions of the p-type transistors may be boron and/or gallium doped epitaxial silicon germanium. However, other material systems may be used. The epitaxial source and drain materials may be deposited using any suitable technique or techniques such as CVD including dopant materials.

The flowable dielectric material structures may then be removed using as such as removal of the dummy gate to expose the gate region of the PMOS transistors, and selective etch processing. Such processing removes the sacrificial flowable dielectric material structures while maintaining the desired compressive stress/strain profile in the channel material (i.e., semiconductor structures or nanowires) of the p-type transistors.

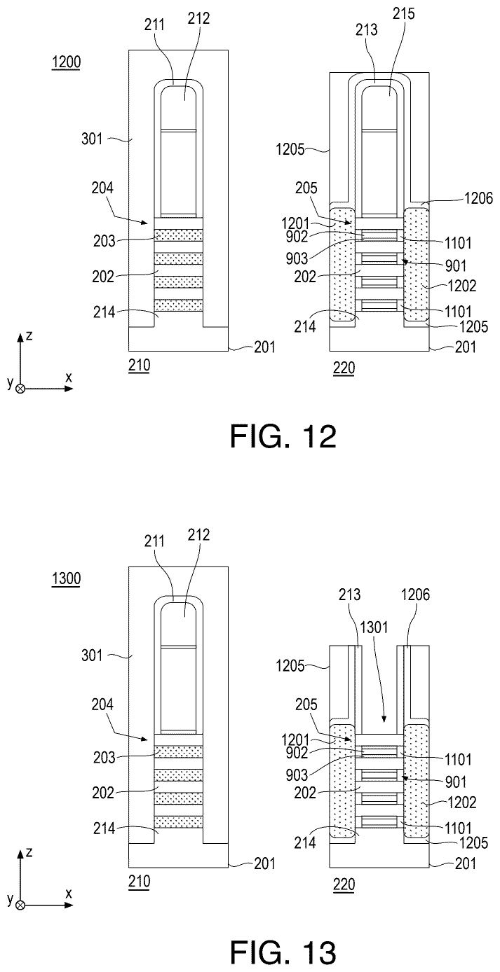

FIG. 12 is a cross-sectional side view of an example integrated circuit structure 1200 similar to integrated circuit structure 1100, after the epitaxial growth of source structure 1201 and drain structure 1202 of p-type transistor structure 220. In some embodiments, source structure 1201 and drain structure 1202 each include an epitaxial nucleation layer (not shown) and a bulk epitaxial material. For example, epitaxial nucleation layers may have a lower dopant concentration than a bulk of the epitaxial material of source structure 1201 and drain structure 1202.

Source structure 1201 and drain structure 1202 may be fabricated using CVD or other epitaxial deposition techniques. Source structure 1201 and drain structure 1202 are epitaxial to exposed ends of stack 205 of semiconductor structures 202. Due to the presence of recessed dielectric structures 901, the epitaxial material of source structure 1201 and drain structure 1202 imparts a compressive stress on semiconductor structures 202 of p-type transistor structure 220. As discussed, source structure 1201 and drain structure 1202 may be epitaxial bodies such as boron and/or gallium doped epitaxial silicon and germanium (SiGe). As shown, a dielectric conformal layer 1206 and a field dielectric 1205 may be formed over source structure 1201 and drain structure 1202. Dielectric conformal layer 1206 and field dielectric 1205 may be any suitable dielectric materials such as silicon nitride, silicon oxynitride, silicon carbide, or silicon oxygen carbon, in any combination.

FIG. 13 is a cross-sectional side view of an example integrated circuit structure 1300 similar to integrated circuit structure 1200, after removal of dummy gate structure 215 and portions of dielectric spacers 213 and dielectric conformal layer 1206. Dummy gate structure 215 and portions of dielectric spacers 213 and dielectric conformal layer 1206 may be removed using any suitable technique or techniques such as planarization (e.g., chemical mechanical polishing) followed by selective dummy gate structure 215 (e.g., polysilicon) removal. Removal of dummy gate structure 215 provides an opening 1301 to access semiconductor structures 202 and recessed dielectric structures 901, with access to recessed dielectric structures 901 being into or out of the page with respect to the view of FIG. 13.

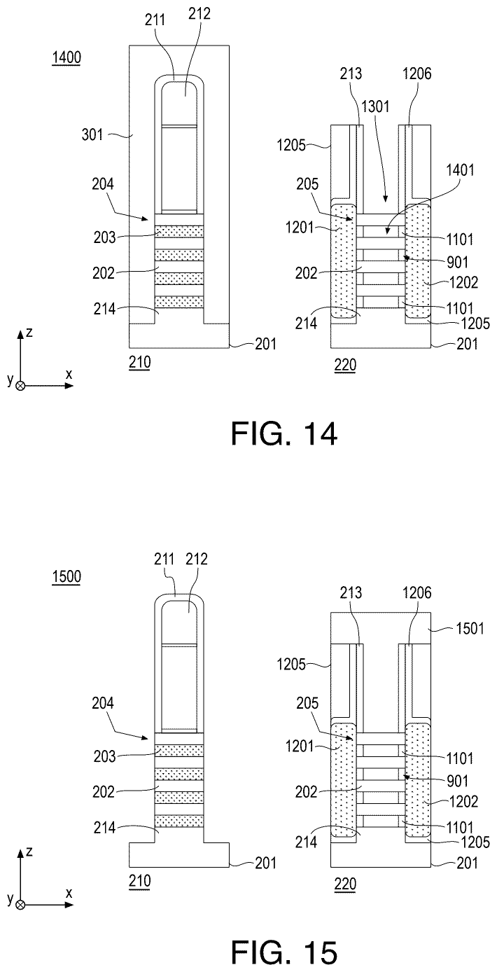

FIG. 14 is a cross-sectional side view of an example integrated circuit structure 1400 similar to integrated circuit structure 1300, after removal of recessed dielectric structures 901 to expose semiconductor structures 202 and form openings 1401. Recessed dielectric structures 901 may be removed using any suitable technique or techniques such as selective wet etch techniques, such that the processing leaves semiconductor structures 202, with spacer structures 1101 on and between ends of semiconductor structures 202 and on source structure 1201 and drain structure 1202.

Returning to FIG. 1, processing continues at operation 106, where the mask formed at operation 103 is removed, the p-type transistor structures are masked, sacrificial material layers of the n-type transistor structures are recessed, and source and gate to source and gate to drain spacers may be formed for the n-type transistor structures. As discussed, the dielectric spacers ultimately insulate a gate structure from each of a source structure and a drain structure. The PMOS transistor mask may be any suitable material or materials that protect p-type transistor structures during selective processing of the NMOS transistors, such as silicon oxide, and the mask may be formed by, for example, applying a bulk material layer, optional planarization, forming a patterned layer on the bulk material layer, and etch processing to form a patterned mask layer.

The sacrificial material layers may be recessed with respect to the semiconductor structures using any suitable technique or techniques. In some embodiments, they are recessed using a selective etch that selectively removes the materials of the sacrificial material layers (e.g., the flowable oxide fill and dielectric liner) relative to the semiconductor structures. For example, an etch selective to silicon germanium may be performed. The dielectric spacers may be formed using any suitable technique or techniques such as deposition and anisotropic directional etching techniques. The dielectric spacers formed at operation 106 may be the same material as those discussed with respect to operation, or they may be different. For example, the NMOS and PMOS transistors may have the same spacer materials in some embodiments. However, different materials may be used.

FIG. 15 is a cross-sectional side view of an example integrated circuit structure 1500 similar to integrated circuit structure 1400, after removal of mask layer 301 and formation of a mask layer 1501 to cover p-type transistor structure 220 while exposing n-type transistor structure 210. Mask layer 1501 may be any suitable material or materials such as silicon oxide or other protective materials. In some embodiments, mask layer 1501 is formed by applying a bulk material layer, planarization, and patterning. Mask layer 1501 covers p-type transistor structure 220 while exposing n-type transistor structure 210 for processing to apply tensile stress engineering to semiconductor structures 202 of n-type transistor structure 210. Any material build-up or damage to mask layer 1501 during such processing is not illustrated for the sake of clarity of presentation.

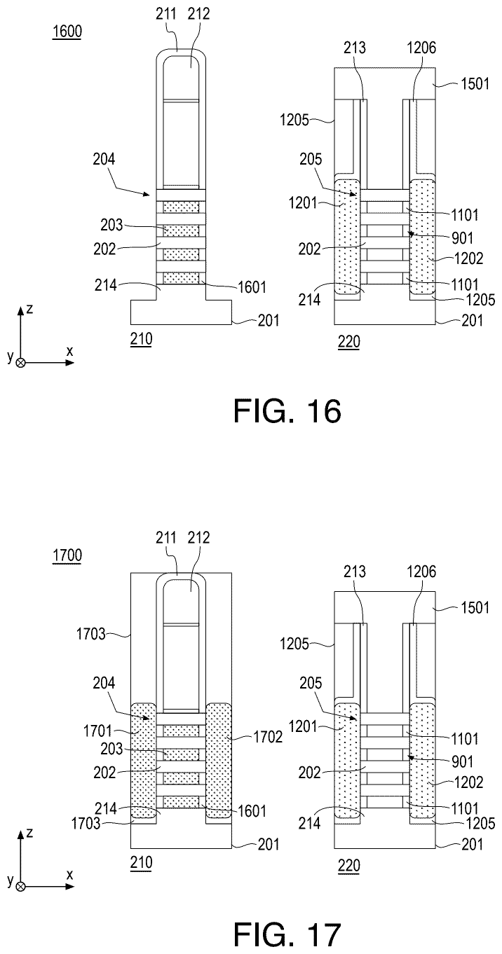

FIG. 16 is a cross-sectional side view of an example integrated circuit structure 1600 similar to integrated circuit structure 1500, after recessing sacrificial material structures 203 and fabrication of spacer structures 1601. In some embodiments, sacrificial material structures 203 are recessed using selective etch techniques. Spacer structures 1601 may then be formed by, for example, depositing a spacer material such as silicon oxide, silicon nitride, silicon oxynitride, or the like using any suitable technique or techniques such as ALD, PECVD, or CVD. Portions of the spacer material may then be removed using anisotropic directional etching techniques, leaving spacer structures 1601. As discussed, spacer structures 1601 may be any suitable dielectric material such as silicon oxide (i.e., a dielectric including silicon and oxygen), silicon nitride (i.e., a dielectric including silicon and nitrogen), silicon oxynitride (i.e., a dielectric including silicon, oxygen, and nitrogen). However, other material systems may be used.

Returning to FIG. 1, processing continues at operation 107, where epitaxial n-type source and drain materials are grown or deposited via the exposed ends of the stacks of interleaved semiconductor material layers in the presence of the discussed substantially lattice matched sacrificial materials (e.g., SiGe) for the NMOS transistors, and the sacrificial materials are then removed to release the semiconductor material layers. Notably, the presence of the substantially lattice matched sacrificial materials sets or locks in the desired stress engineering (i.e., tensile stress) in the channel of the NMOS transistor structures.

The epitaxial growth of source and drain structures in the presence of substantially lattice matched sacrificial materials may include a single bulk material, or growth of an epitaxial nucleation layer followed by bulk growth or deposition. In some embodiments, the epitaxial nucleation layer and bulk epitaxial materials are grown or deposited in the same process chamber using differing deposition parameters. The n-type source and drain materials may be any suitable materials having n-type conductivity such as doped silicon. In some embodiments, the source and drain regions of the n-type transistors are phosphorous and/or arsenic doped epitaxial silicon. The epitaxial source and drain materials may be deposited using any suitable technique or techniques such as CVD.

FIG. 17 is a cross-sectional side view of an example integrated circuit structure 1700 similar to integrated circuit structure 1600, after the epitaxial growth of source structure 1701 and drain structure 1702 of n-type transistor structure 210. In some embodiments, source structure 1701 and drain structure 1702 each include an epitaxial nucleation layer (not shown) and a bulk epitaxial material. For example, epitaxial nucleation layers may have a lower dopant concentration than a bulk of the epitaxial material of source structure 1701 and drain structure 1702. In some embodiments, source structure 1701 and drain structure 1702 are formed using CVD. Source structure 1701 and drain structure 1702 are epitaxial to exposed ends of stack 204 of semiconductor structures 202. Due to the presence of sacrificial material structures 203, the epitaxial material of source structure 1701 and drain structure 1702 advantageously imparts a tensile stress on semiconductor structures 202 of n-type transistor structure 210. Source structure 1701 and drain structure 1702 may be epitaxial bodies such as phosphorous and/or arsenic doped epitaxial silicon. Furthermore, a field dielectric 1703 may be formed over source structure phosphorous and/or arsenic doped epitaxial silicon. In some embodiments, a dielectric conformal layer (similar to dielectric conformal layer 1206) is also fabricated, with field dielectric 1703 and the optional dielectric conformal layer being any suitable dielectric materials such as silicon nitride, silicon oxynitride, silicon carbide, or silicon oxygen carbon, in any combination.

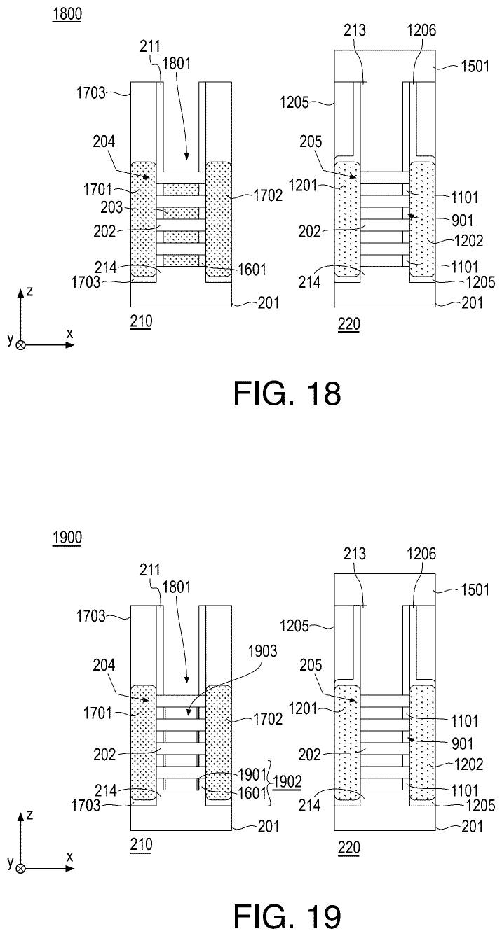

FIG. 18 is a cross-sectional side view of an example integrated circuit structure 1800 similar to integrated circuit structure 1700, after removal of dummy gate structure 212 and portions of dielectric spacers 211. Dummy gate structure 212 and portions of dielectric spacers 211 may be removed using any suitable technique or techniques such as planarization followed by selective dummy gate structure 212 (e.g., polysilicon) removal. Removal of dummy gate structure 212 provides an opening 1801 to access semiconductor structures 202 and sacrificial material structures 203, with access to sacrificial material structures 203 being into or out of the page with respect to the view of FIG. 18.

FIG. 19 is a cross-sectional side view of an example integrated circuit structure 1900 similar to integrated circuit structure 1800, after removal of portions of sacrificial material structures 203 to release or expose semiconductor structures 202 and to form spacer structures 1902, which each include spacer structures 1601 and a lateral material structure 1901, and openings 1903. A portion or majority of sacrificial material structures 203 may be removed using any suitable technique or techniques such as selective wet etch techniques, such that the processing leaves lateral material structure 1901 on and immediately adjacent source structure 1701 and drain structure 1702. Lateral material structure 1901 are the material of sacrificial material structures 203 (e.g., silicon germanium) and advantageously provide isolation between a resultant gate structure and source structure 1701 and between the gate structure and drain structure 1702. Details of spacer structures 1902 are discussed further herein below with respect to FIG. 20. As shown, removal of portions of sacrificial material structures 203 releases semiconductor structures 202, which extend between source structure 1701 and drain structure 1702, and maintain the discussed stress engineering (i.e., tensile stress) after removal of sacrificial material structures 203.

Returning to FIG. 1, processing continues at operation 108, where the mask formed at operation 106 is removed, and gate structures are formed on the exposed semiconductor structures. The gate structures include a gate dielectric material on at least portions of the semiconductor structures, and a gate electrode (e.g., gate metal) on the gate dielectric material. The gate structure may be formed using any suitable technique or techniques. In some embodiments, the gate dielectric material is formed using conformal deposition processing, and the gate electrode is formed by conformal deposition (of a work function metal) followed by metal fill. However, other fabrication techniques may be used.

Processing continues at operation 109, where any or all of the source structure, drain structure, and gate structure of each of the n-type transistor structure and the p-type transistor structure are contacted by frontside metal contacts using any suitable technique or techniques such as patterning and metal deposition processing as is known in the art. For example, frontside contacts may be made to any one or more of the source, drain, and gate of n-type transistor structure and the p-type transistor structure being fabricated. For example, a transistor structure is a three terminal device to be contacted at the source, drain, and gate, and any of these may be contacted from the frontside or backside of the device structure. The frontside contacts are then interconnected by metallization layers over the frontside contact. In some embodiments, the gate and drain of the transistor structure are contacted from the frontside to provide signal routing and the source of the transistor structure is contacted from the backside to provide power delivery. However, any interconnect routing may be used.

FIG. 20 is a cross-sectional side view of an example integrated circuit structure 2000 similar to integrated circuit structure 1900, after formation of gate structure 2009 of n-type transistor structure 210 and gate structure 2013 of p-type transistor structure 220, and after formation of a source contact 2001, a drain contact 2002, and a gate contact (not shown) of n-type transistor structure 210, and a source contact 2005, a drain contact 2006, and a gate contact (not shown) of p-type transistor structure 220, all within a dielectric material 2004, which may be any suitable material such as a silicon oxide, silicon nitride, silicon oxynitride, or the like. Although illustrated with respect to gate structure 2009 and gate structure 2013 being formed simultaneously, in some embodiments, some components of gate structure 2009 and gate structure 2013 may be formed separately. For example, gate structure 2009 and gate structure 2013 may deploy different work function metals.

As shown, gate structure 2009 includes a gate dielectric layer 2007 and a gate electrode 2008 and gate structure 2013 includes a gate dielectric layer 2011 and a gate electrode 2012. In some embodiments, gate structures 2009, 2013 are formed by conformal deposition of gate dielectric layers 2007, 2011 followed by conformal deposition of a work function metal of gate electrodes 2008, 2012, which is followed by metal fill of a remainder of gate electrodes 2008, 2012.

In some embodiments, each of gate dielectric layers 2007, 2011 includes a layer that is or includes aluminum oxide, hafnium oxide, zirconium oxide, titanium silicon oxide, hafnium silicon oxide, or silicon nitride. For example, each of gate dielectric layers 2007, 2011 may include aluminum and oxygen; hafnium and oxygen; zirconium and oxygen; titanium, silicon, and oxygen; hafnium, silicon, and oxygen; or silicon and nitrogen. In some embodiments, gate electrodes 2008, 2012 each includes a work function layer of platinum, nickel, titanium nitride, or tantalum nitride and a fill metal such as tungsten. However, other material systems may be used.

As also shown in FIG. 20, integrated circuit structure 2000 includes frontside source contacts 2001, 2005 in contact with source structures 1701, 1201 and frontside drain contacts 2002, 2006 in contact with drain structures 1702, 1202, respectively. Integrated circuit structure 2000 may further include a frontside gate contact (not shown) in contact with one or both of gate electrodes 2008, 2012. For example, the gate contact(s) may be into or out of the page of the illustrated cross section. Frontside source contacts 2001, 2005, frontside drain contacts 2002, 2006, and the frontside gate contacts may be formed using operations known in the art such as lithography patterning of vias and via fill and optional planarization. Such components may include any suitable materials. For example, each may include a liner material such as titanium nitride and a fill metal such as tungsten. However, other material systems may be used. Over integrated circuit structure 2000, frontside metallization layers may be formed using any suitable technique or techniques such as dual damascene techniques, single damascene techniques, subtractive metallization patterning techniques, or the like. Frontside metallization layers are illustrated herein below with respect to FIG. 21. In some embodiments, only frontside metallization layers are used. In other embodiments, after fabrication of the frontside metallization layers, the workpiece may be mounted to a carrier wafer and backside contacts and metallization layers may be fabricated.

Integrated circuit structure 2000 includes n-type transistor structure 210 including stack 204 of semiconductor structures 202 that extend between source structure 1701 and drain structure 1702, gate structure 2009 coupled to stack 204 of semiconductor structures 202, and spacer structures 1902 on and between the gate structure 2009 and source structure 1701 and on and between the gate structure 2009 and drain structure 1702. As shown, spacer structure 1902 includes spacer structures 1601, which includes a dielectric material, and lateral material structure 1901, which includes silicon and germanium. Integrated circuit structure 2000 further includes p-type transistor structure 220 including stack 205 of semiconductor structures 202 that extend between source structure 1201 and drain structure 1202, gate structure 2013 coupled stack 205 of semiconductor structures 202, and spacer structures 1101 on and between gate structure 2013 and source structure 1201 and on and between gate structure 2013 and drain structure 1202. As discussed, spacer structures 1101 include a dielectric material and is absent germanium. In some embodiments, the dielectric material of spacer structures 1101 and the dielectric material of spacer structures 1601 are the same. For example, the dielectric material may be a compound including silicon and nitrogen such as silicon nitride or silicon oxynitride.

As discussed, in some embodiments, the release of semiconductor structures 202 in the presence of spacer structures 1601 advantageously leaves a portion of the sacrificial lattice matched material as lateral material structure 1901. For example, lateral material structure 1901 may be silicon germanium. As shown in enlarged view 2020, in some embodiments, spacer structure 1601 and lateral material structure 1901 meet at an interface 2021. In some embodiments, interface 2021 has a first vertical thickness Ti (interface thickness) and one or both of spacer structure 1601 and lateral material structure 1901 have a second vertical thickness Tb (bulk thickness) such that the bulk thickness Tb is greater than the interface thickness Ti. The term bulk thickness Tb indicates a thickness at or toward a center of the component and may be taken at the center or may be an average of multiple measured thicknesses, for example. The bulk thickness Tb of one or both of spacer structure 1601 and lateral material structure 1901 may be any suitable value such as a bulk thickness Tb of not less than 5 nm and not more than 12 nm. In some embodiments, the interface thickness Ti is not more than 90% of the bulk thickness Tb. In some embodiments, the interface thickness Ti is not more than 80% of the bulk thickness Tb. In some embodiments, the interface thickness Ti is not more than 75% of the bulk thickness Tb. Other thicknesses may be used.

Returning to FIG. 1, processing continues at operation 110, where backside metallization is optionally fabricated opposite the frontside metallization with respect to a device layer including the discussed integrated structures, additional fabrication processes may be completed, and the resultant structure may be output. Such processing may include backend processing, dicing, packaging, assembly, and so on. The resultant device (e.g., integrated circuit die) may then be implemented in any suitable form factor device such as a laptop, a netbook, a notebook, an ultrabook, a smartphone, a tablet, a personal digital assistant, an ultra-mobile PC, a mobile phone, a desktop computer, a server, a printer, a scanner, a monitor, a set-top box, an entertainment control unit, a digital camera, a portable music player, a digital video recorder, or the like.

FIG. 21 is a cross-sectional side view of a multi-layer integrated circuit device structure 2100 incorporating n-type transistor structure 210 and p-type transistor structure 220, arranged in accordance with at least some embodiments of the present disclosure. Although illustrated and discussed with respect to n-type transistor structure 210 and p-type transistor structure 220 altered with use of backside source contacts, any integrated circuit structures discussed herein such n-type transistor structure 210 and p-type transistor structure 220 having frontside source contacts may be deployed in the context of multi-layer integrated circuit device structure 2100. As shown, multi-layer integrated circuit device structure 2100 is incorporated in integrated circuit (IC) die 2107 such that multi-layer integrated circuit device structure 2100 includes frontside metallization layers 2101 (or frontside interconnect layers) and backside metallization layers 2102 (or backside interconnect layers). Frontside metallization layers 2101 and backside metallization layers 2102 may be formed using any suitable technique or techniques such as dual damascene techniques, single damascene techniques, subtractive metallization patterning techniques, or the like. In some embodiments, backside metallization layers 2102 are not deployed.

In some embodiments, interconnectivity, signal routing, power-delivery, and the like may be provided by frontside metallization layers 2101. Adjacent metallization layers, such as metallization interconnects 2110, are interconnected by vias, such as vias 2103, that may be characterized as part of the metallization layers or between the metallization layers. As shown, in some embodiments, frontside metallization layers 2101 are formed over and immediately adjacent n-type transistor structure 210 and p-type transistor structure 220. In the illustrated example, frontside metallization layers 2101 include M0, V0, M1, M2/V1, M3/V2, and M4/V3. However, frontside metallization layers 2101 may include any number of metallization layers such as six, eight, or more metallization layers.

Similarly, backside metallization layers 2102, may be used for interconnectivity, signal routing, power-delivery, and any other suitable electrical connectivity. In some embodiments, frontside metallization layers 2101 are used exclusively for signal routing and backside metallization layers 2102 are used exclusively for power delivery. However, any interconnection architecture may be used. In the illustrated example, package level interconnects 2111 are provided on or over a device backside as bumps over a passivation layer 2105. However, package level interconnects 2111 may be provided using any suitable interconnect structures such as bond pads, solder bumps, etc. As shown, in some embodiments, backside metallization layers 2102 are formed over and immediately adjacent n-type transistor structure 210 and p-type transistor structure 220 such that a device layer 2104 including n-type transistor structure 210 and p-type transistor structure 220 is between frontside metallization layers 2101 and backside metallization layers 2102. In the illustrated example, backside metallization layers 2102 include BM0, BM1, and BM2 with intervening via layers. However, backside metallization layers 2102 may include any number of metallization layers such as three, four, or more metallization layers.

In some embodiments, an integrated circuit structure including n-type transistor structure 210 and p-type transistor structure 220 is deployed in a monolithic integrated circuit (IC) die 2107 including gate-all-around field effect transistor structures (e.g., GAA-FETs) including any of the discussed components and characteristics. As shown, a power supply 2106 may be coupled to IC die 2107, such that power supply 2106 may include a battery, voltage converter, power supply circuitry, or the like.

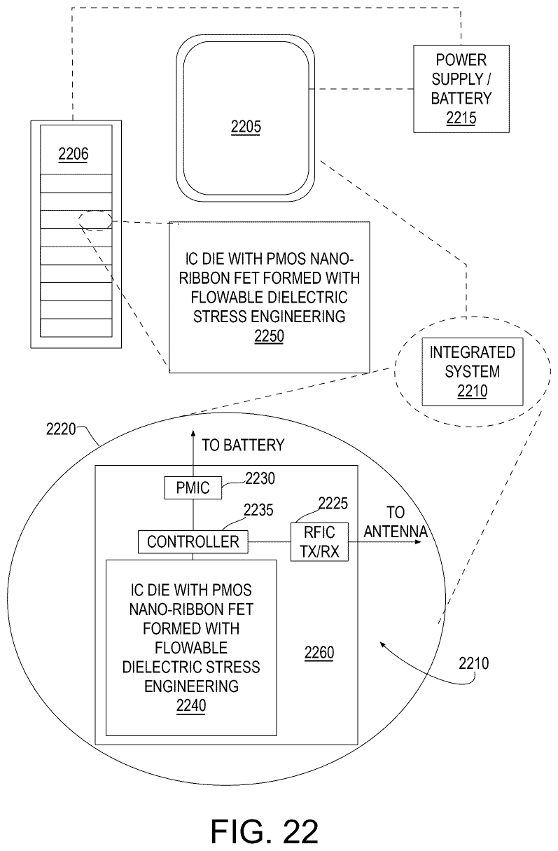

FIG. 22 illustrates exemplary systems employing integrated circuit structures with an n-type transistor integrated with a p-type transistor such that the n-type transistor and the p-type transistor have selective stress engineering, in accordance with some embodiments. The system may be a mobile computing platform 2205 and/or a data server machine 2206, for example. Either may employ a component assembly including an IC die employing integrated circuit structures with an n-type transistor integrated with a p-type transistor such that the n-type transistor p-type transistor having selective stress engineering as described elsewhere herein. Server machine 2206 may be any commercial server, for example including any number of high-performance computing platforms disposed within a rack and networked together for electronic data processing, which in the exemplary embodiment includes an IC die assembly 2250 with an IC die employing integrated circuit structures with an n-type transistor integrated with a p-type transistor such that the n-type transistor p-type transistor having selective stress engineering as described elsewhere herein. Mobile computing platform 2205 may be any portable device configured for each of electronic data display, electronic data processing, wireless electronic data transmission, or the like. For example, mobile computing platform 2205 may be any of a tablet, a smart phone, a laptop computer, etc., and may include a display screen (e.g., a capacitive, inductive, resistive, or optical touchscreen), a chip-level or package-level integrated system 2210, and a battery 2215. Although illustrated with respect to mobile computing platform 2205, in other examples, chip-level or package-level integrated system 2210 and a battery 2215 may be implemented in a desktop computing platform, an automotive computing platform, an internet of things platform, or the like. As discussed below, in some examples, the disclosed systems may include a sub-system 2260 such as a system on a chip (SOC) or an integrated system of multiple ICs, which is illustrated with respect to mobile computing platform 2205.

Whether disposed within integrated system 2210 illustrated in expanded view 2220 or as a stand-alone packaged device within data server machine 2206, sub-system 2260 may include memory circuitry and/or processor circuitry 2240 (e.g., RAM, a microprocessor, a multi-core microprocessor, graphics processor, etc.), a power management integrated circuit (PMIC) 2230, a controller 2235, and a radio frequency integrated circuit (RFIC) 2225 (e.g., including a wideband RF transmitter and/or receiver (TX/RX)). As shown, one or more IC dies, such as memory circuitry and/or processor circuitry 2240 may be fabricated and implemented such that one or more have an IC die employing integrated circuit structures with an n-type transistor integrated with a p-type transistor such that the n-type transistor p-type transistor having selective stress engineering as described herein. In some embodiments, RFIC 2225 includes a digital baseband and an analog front end module further comprising a power amplifier on a transmit path and a low noise amplifier on a receive path). Functionally, PMIC 2230 may perform battery power regulation, DC-to-DC conversion, etc., and so has an input coupled to battery 2215, and an output providing a current supply to other functional modules. As further illustrated in FIG. 22, in the exemplary embodiment, RFIC 2225 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. Memory circuitry and/or processor circuitry 2240 may provide memory functionality for sub-system 2260, high level control, data processing and the like for sub-system 2260. In alternative implementations, each of the SOC modules may be integrated onto separate ICs coupled to a package substrate, interposer, or board.

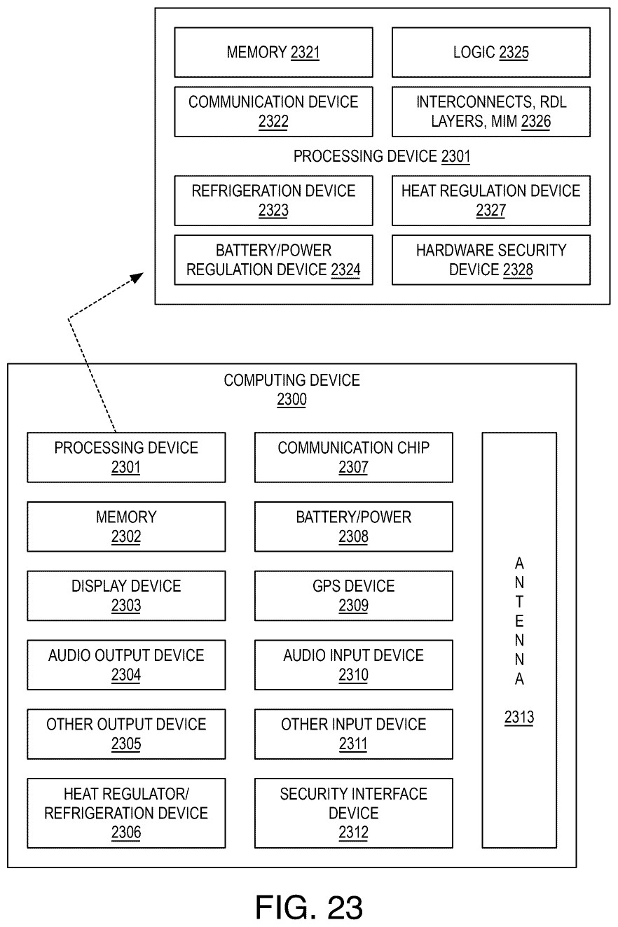

FIG. 23 is a block diagram of a computing device 2300, in accordance with some embodiments. For example, one or more components of computing device 2300 may include any of the integrated circuit structures with an n-type transistor integrated with a p-type transistor such that the n-type transistor p-type transistor having selective stress engineering as discussed elsewhere herein. A number of components are illustrated in FIG. 23, but any one or more of these components may be omitted or duplicated, as suitable for the application. In some embodiments, some of the components included in computing device 2300 may be attached to one or more printed circuit boards (e.g., a motherboard). In some embodiments, various ones of these components may be fabricated onto a single system-on-a-chip (SoC) die or implemented with a disintegrated plurality of chiplets or tiles packaged together. Any of such packaged components may include integrated circuit structures with an n-type transistor integrated with a p-type transistor such that the n-type transistor p-type transistor having selective stress engineering, for example, as discussed herein. Additionally, in various embodiments, computing device 2300 may not include one or more of the components illustrated in FIG. 23, but computing device 2300 may include interface circuitry for coupling to the one or more components. For example, computing device 2300 may not include a display device 2303, but may include display device interface circuitry (e.g., a connector and driver circuitry) to which display device 2303 may be coupled.

Computing device 2300 may include a processing device 2301 (e.g., one or more processing devices). As used herein, the term processing device or processor indicates a device that processes electronic data from registers and/or memory to transform that electronic data into other electronic data that may be stored in registers and/or memory. Processing device 2301 may include a memory 2321, a communication device 2322, a refrigeration/active cooling device 2323, a battery/power regulation device 2324, logic 2325, interconnects 2326, a heat regulation device 2327, and a hardware security device 2328.

Processing device 2301 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable compute units.

Processing device 2301 may include a memory 2302, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, processing device 2301 shares a package with memory 2302. This memory may be used as cache memory and may include embedded dynamic random-access memory (eDRAM) or spin transfer torque magnetic random-access memory (STT-M RAM).

Computing device 2300 may include a heat regulation/refrigeration device 2306. Heat regulation/refrigeration device 2306 may maintain processing device 2301 (and/or other components of computing device 2300) at a predetermined low temperature during operation. This predetermined low temperature may be any temperature discussed elsewhere herein.

In some embodiments, computing device 2300 may include a communication chip 2307 (e.g., one or more communication chips). For example, the communication chip 2307 may be configured for managing wireless communications for the transfer of data to and from computing device 2300. The term “wireless” and its derivatives may be used to describe circuits, devices, systems, methods, techniques, communications channels, etc., that may communicate data through the use of modulated electromagnetic radiation through a nonsolid medium.

Computing device 2300 may include any photonics structure discussed herein that may facilitate communication between one or more instances of processing device 2301 and/or one or more instances of memory 2302, for example.

Computing device 2300 may include battery/power circuitry 2308. Battery/power circuitry 2308 may include one or more energy storage devices (e.g., batteries or capacitors) and/or circuitry for coupling components of computing device 2300 to an energy source separate from computing device 2300 (e.g., AC line power).

Computing device 2300 may include a display device 2303 (or corresponding interface circuitry, as discussed above). Display device 2303 may include any visual indicators, such as a heads-up display, a computer monitor, a projector, a touchscreen display, a liquid crystal display (LCD), a light-emitting diode display, or a flat panel display, for example.

Computing device 2300 may include an audio output device 2304 (or corresponding interface circuitry, as discussed above). Audio output device 2304 may include any device that generates an audible indicator, such as speakers, headsets, or earbuds, for example.

Computing device 2300 may include an audio input device 2310 (or corresponding interface circuitry, as discussed above). Audio input device 2310 may include any device that generates a signal representative of a sound, such as microphones, microphone arrays, or digital instruments (e.g., instruments having a musical instrument digital interface (MIDI) output).

Computing device 2300 may include a global positioning system (GPS) device 2309 (or corresponding interface circuitry, as discussed above). GPS device 2309 may be in communication with a satellite-based system and may receive a location of computing device 2300, as known in the art.

Computing device 2300 may include another output device 2305 (or corresponding interface circuitry, as discussed above). Examples include an audio codec, a video codec, a printer, a wired or wireless transmitter for providing information to other devices, or an additional storage device.

Computing device 2300 may include another input device 2311 (or corresponding interface circuitry, as discussed above). Examples may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 2300 may include a security interface device 2312. Security interface device 2312 may include any device that provides security measures for computing device 2300 such as intrusion detection, biometric validation, security encode or decode, managing access lists, malware detection, or spyware detection.

Computing device 2300 may include an antenna 2313. Antenna 2313 may include any device that translates electrical current to radio waves and/or translates radio waves to electrical current.

Computing device 2300, or a subset of its components, may have any appropriate form factor, such as a server or other networked computing component, a mobile device, a printer, a scanner, a monitor, a set-top box, an entertainment control unit, a vehicle control unit, a digital camera, a digital video recorder, or a wearable computing device.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the invention is not limited to the embodiments so described, but can be practiced with modification and alteration without departing from the scope of the appended claims. For example, the above embodiments may include specific combinations of features as further provided below.

The following pertain to exemplary embodiments.

In one or more first embodiments, an apparatus comprises an n-type transistor comprising a plurality of first semiconductor structures extending between a first source structure and a first drain structure, a first gate structure coupled to the first semiconductor structures, and a first spacer structure on and between the first gate structure and the first source structure or the first drain structure, the first spacer structure comprising a first dielectric material and germanium, and a p-type transistor comprising a plurality of second semiconductor structures extending between a second source structure and a second drain structure, a second gate structure coupled to the second semiconductor structures, and a second spacer structure between the second gate structure and the second source structure or the second drain structure, the second spacer structure comprising the first dielectric material or a second dielectric material, and absent germanium.

In one or more second embodiments, further to the first embodiments, the second spacer structure comprises the first dielectric material, and the first dielectric material comprises a compound comprising silicon and nitrogen.

In one or more third embodiments, further to the first or second embodiments, the first spacer structure comprises a first structure adjacent the first source structure or the first drain structure and a second structure adjacent the first gate structure, the first structure comprising the first dielectric material and the second structure comprising silicon and germanium.

In one or more fourth embodiments, further to the first through third embodiments, an interface between the first structure and the second structure has a first vertical thickness and a bulk portion of the first structure has a second vertical thickness greater than the first vertical thickness.

In one or more fifth embodiments, further to the first through fourth embodiments, the first gate structure and the second gate structure each comprise a same gate dielectric material and a same gate electrode material.

In one or more sixth embodiments, further to the first through fifth embodiments, the apparatus further comprises an integrated circuit (IC) die comprising the n-type transistor and the p-type transistor, and a power supply coupled to the IC die.

In one or more seventh embodiments, an apparatus comprises an n-type transistor comprising a first nanowire extending between a first source and a first drain, a first gate coupled to the first nanowire, and a first spacer between the first gate and the first source or the first drain, the first spacer comprising a first portion and a second portion, the first portion adjacent the first source or the first drain and comprising a first dielectric material, and the second portion adjacent the first gate and comprising germanium, and a p-type transistor comprising a second nanowire extending between a second source and a second drain, a second gate coupled to the second nanowire, and a second spacer comprising the first dielectric material or a second dielectric material, the first dielectric material or the second dielectric material of the second spacer on and between the second gate and the second source or the second drain.

In one or more eighth embodiments, further to the seventh embodiments, the second portion of the first spacer further comprises silicon.

In one or more ninth embodiments, further to the seventh or eighth embodiments, the second spacer comprises the first dielectric material, and the first dielectric material comprises a compound comprising silicon and nitrogen.

In one or more tenth embodiments, further to the seventh through ninth embodiments, interface between the first portion and the second portion has a first vertical thickness and a bulk portion of the first portion has a second vertical thickness greater than the first vertical thickness.

In one or more eleventh embodiments, further to the seventh through tenth embodiments, the first gate and the second gate each comprise a same gate dielectric material and a same gate electrode material.

In one or more twelfth embodiments, further to the seventh through eleventh embodiments, the apparatus further comprises an integrated circuit (IC) die comprising the n-type transistor and the p-type transistor, and a power supply coupled to the IC die.

In one or more thirteenth embodiments, a method comprises releasing a plurality of first nanowires of an n-type transistor structure by removing first sacrificial materials from between the first nanowires, forming a sacrificial material structure on and between the first nanowires, the sacrificial material structure comprising a flowable dielectric material, growing n-type epitaxial source and drain structures from the first nanowires and adjacent the sacrificial material structure, removing the sacrificial material structure, and coupling a gate structure to the first nanowires.

In one or more fourteenth embodiments, further to the thirteenth embodiments, the sacrificial material structure comprises a dielectric liner on the first nanowires and a flowable oxide on the dielectric liner.

In one or more fifteenth embodiments, further to the thirteenth or fourteenth embodiments, wherein the dielectric liner comprises silicon and at least one of oxygen and nitrogen.

In one or more sixteenth embodiments, further to the thirteenth through fifteenth embodiments, the method further comprises recessing the sacrificial material structure to form openings between exposed ends of the first nanowires, and filling the openings with a dielectric material, such that the n-type epitaxial source and drain structures are grown adjacent the dielectric material.

In one or more seventeenth embodiments, further to the thirteenth through sixteenth embodiments, said coupling the gate structure to the first nanowires comprises forming the gate structure on the dielectric material.

In one or more eighteenth embodiments, further to the thirteenth through seventeenth embodiments, during said releasing the plurality of first nanowires, forming the sacrificial material structure, and growing the n-type epitaxial source and drain structures, a p-type transistor structure adjacent the n-type transistor structure is covered by a mask material.

In one or more nineteenth embodiments, further to the thirteenth through eighteenth embodiments, the method further comprises growing p-type epitaxial source and drain structures from second nanowires of the p-type transistor structure and adjacent second sacrificial materials between the second nanowires.

In one or more twentieth embodiments, further to the thirteenth through nineteenth embodiments, coupling the gate structure to the first nanowires comprises simultaneously forming a gate dielectric material on the first nanowires and the second nanowires and simultaneously forming a gate electrode on the gate dielectric material.

It will be recognized that the invention is not limited to the embodiments so described, but can be practiced with modification and alteration without departing from the scope of the appended claims. For example, the above embodiments may include specific combination of features. However, the above embodiments are not limited in this regard and, in various implementations, the above embodiments may include undertaking only a subset of such features, undertaking a different order of such features, undertaking a different combination of such features, and/or undertaking additional features than those features explicitly listed. The scope of the invention should, therefore, be determined with reference to the appended claims, along with the full scope of equivalents to which such claims are entitled.

What is claimed is:

1. An apparatus, comprising:
an n-type transistor comprising a plurality of first semiconductor structures extending between a first source structure and a first drain structure, a first gate structure coupled to the first semiconductor structures, and a first spacer structure on and between the first gate structure and the first source structure or the first drain structure, the first spacer structure comprising a first dielectric material and germanium; and
a p-type transistor comprising a plurality of second semiconductor structures extending between a second source structure and a second drain structure, a second gate structure coupled to the second semiconductor structures, and a second spacer structure between the second gate structure and the second source structure or the second drain structure, the second spacer structure comprising the first dielectric material or a second dielectric material, and absent germanium.

2. The apparatus of claim 1, wherein the second spacer structure comprises the first dielectric material, and wherein the first dielectric material comprises a compound comprising silicon and nitrogen.

3. The apparatus of claim 1, wherein the first spacer structure comprises a first structure adjacent the first source structure or the first drain structure and a second structure adjacent the first gate structure, the first structure comprising the first dielectric material and the second structure comprising silicon and germanium.

4. The apparatus of claim 3, wherein an interface between the first structure and the second structure has a first vertical thickness and a bulk portion of the first structure has a second vertical thickness greater than the first vertical thickness.

5. The apparatus of claim 1, wherein the first gate structure and the second gate structure each comprise a same gate dielectric material and a same gate electrode material.

6. The apparatus of claim 1, further comprising:
an integrated circuit (IC) die comprising the n-type transistor and the p-type transistor; and
a power supply coupled to the IC die.

7. An apparatus, comprising:
an n-type transistor comprising a first nanowire extending between a first source and a first drain, a first gate coupled to the first nanowire, and a first spacer between the first gate and the first source or the first drain, the first spacer comprising a first portion and a second portion, the first portion adjacent the first source or the first drain and comprising a first dielectric material, and the second portion adjacent the first gate and comprising germanium; and
a p-type transistor comprising a second nanowire extending between a second source and a second drain, a second gate coupled to the second nanowire, and a second spacer comprising the first dielectric material or a second dielectric material, the first dielectric material or the second dielectric material of the second spacer on and between the second gate and the second source or the second drain.

8. The apparatus of claim 7, wherein the second portion of the first spacer further comprises silicon.

9. The apparatus of claim 8, wherein the second spacer comprises the first dielectric material, and wherein the first dielectric material comprises a compound comprising silicon and nitrogen.

10. The apparatus of claim 7, wherein an interface between the first portion and the second portion has a first vertical thickness and a bulk portion of the first portion has a second vertical thickness greater than the first vertical thickness.

11. The apparatus of claim 7, wherein the first gate and the second gate each comprise a same gate dielectric material and a same gate electrode material.

12. The apparatus of claim 7, further comprising:
an integrated circuit (IC) die comprising the n-type transistor and the p-type transistor; and
a power supply coupled to the IC die.

13. A method, comprising:
releasing a plurality of first nanowires of an n-type transistor structure by removing first sacrificial materials from between the first nanowires;
forming a sacrificial material structure on and between the first nanowires, the sacrificial material structure comprising a flowable dielectric material;
growing n-type epitaxial source and drain structures from the first nanowires and adjacent the sacrificial material structure;
removing the sacrificial material structure; and
coupling a gate structure to the first nanowires.

14. The method of claim 13, wherein the sacrificial material structure comprises a dielectric liner on the first nanowires and a flowable oxide on the dielectric liner.

15. The method of claim 14, wherein the dielectric liner comprises silicon and at least one of oxygen and nitrogen.

16. The method of claim 13, further comprising:
recessing the sacrificial material structure to form openings between exposed ends of the first nanowires; and
filling the openings with a dielectric material, wherein the n-type epitaxial source and drain structures are grown adjacent the dielectric material.

17. The method of claim 16, wherein said coupling the gate structure to the first nanowires comprises forming the gate structure on the dielectric material.

18. The method of claim 13, wherein, during said releasing the plurality of first nanowires, forming the sacrificial material structure, and growing the n-type epitaxial source and drain structures, a p-type transistor structure adjacent the n-type transistor structure is covered by a mask material.

19. The method of claim 18, further comprising:
growing p-type epitaxial source and drain structures from second nanowires of the p-type transistor structure and adjacent second sacrificial materials between the second nanowires.

20. The method of claim 19, wherein coupling the gate structure to the first nanowires comprises simultaneously forming a gate dielectric material on the first nanowires and the second nanowires and simultaneously forming a gate electrode on the gate dielectric material.
